(19) United States
(12) Patent Application Publication
(10) Pub. No.: US 2009/0261419 A1
(43) Pub. Date: Oct. 22, 2009

(54) SEMICONDUCTOR DEVICE HAVING ASSIST FEATURES AND MANUFACTURING METHOD THEREOF

(76) Inventors: Shu-Ping Fang, Hsinchu City (TW); Tien-Cheng Lan, Taipei County (TW); Chih-Chien Liu, Taipei City (TW)

Correspondence Address: NORTH AMERICA INTELLECTUAL PROPERTY CORPORATION, P.O. BOX 506, MERRIFIELD, VA, 22116, US

(21) Appl. No.: 12/107,077

(22) Filed: Apr. 22, 2008

(51) Int. Cl. H01L 29/78; H01L 21/76; G03F 7/20

(52) U.S. Cl. 257/368; 257/499; 430/312; 257/E29.255; 257/E21.54

(57) ABSTRACT

A semiconductor device having assist features and manufacturing method thereof includes a substrate having at least an active region and a peripheral region defined thereon. The semiconductor device also includes a plurality of assist features positioned in the peripheral region, or in the active region with a dotted line pattern. The assist features are electrically connected to active circuits formed in the active region, respectively, for serving as redundant circuits that repair or replace defective circuits.

### BACKGROUND OF THE INVENTION

1. Field of the Invention

The invention relates to a semiconductor device and manufacturing method thereof, and more particularly, to a semiconductor device having assist features and manufacturing method thereof.

2. Description of the Prior Art

With progression in integrated circuit manufactures, sizes of semiconductor devices keep shrinking. Therefore problems with feature scale control and thickness control have emerged from the processes. And thus how to reliably produce features in deep sub-half micron has become a critical factor in very large scale integration (VLSI) or ultra large scale integration (ULSI) manufactures. For instance, it is essentially important to form a reliable gate pattern satisfied with requirement of high density when constructing VLSI or ULSI.

However, as the critical dimension (CD) keeps shrinking, the gate pattern and gate profile are easily affected by aspect ratio of the gate during the etching process. Furthermore, CD is susceptible to loading effect generated between different feature densities. Because the iso regions have larger openings in surface area than dense regions, etchant will contact and react with more objective material in the iso regions. Consequently, the etching rate is higher in the iso regions, and more by-products are produced in the iso regions. Thus, uniformity of the wafer after the etching process is adversely affected and even undesirably makes the gate patterns in iso/dense regions different though the resulted gate patterns are required to be identical. Simply speaking, loading effect occurring in iso/dense regions worsens uniformity of the gate patterns in etching process and simultaneously influences gate profiles, while those variations adversely influence gate CD.

In addition, non-uniform surface further faces problems such as formation of recesses after global planarization. To avoid such problem, the dielectric layer is intentionally made thicker therefore an uniform surface might be obtained after the planarization, which is used to downwardly planarize the thicker dielectric to the predetermined thickness. There is no doubt that the thicker dielectric layer and the longer planarization result in more consumption of process time, material, and cost.

### SUMMARY OF THE INVENTION

It is therefore an objective of the present invention to provide a semiconductor device having assist features that is capable of effectively improving surface uniformity and manufacturing method thereof.

According to the claimed invention, a semiconductor device having assist features is provided. The semiconductor device comprises a substrate having an active region defined thereon, one or more first active circuit features formed in the active region, and a plurality of dotted first assist features positioned between portions of the first active circuit feature in the active region.

According to the claimed invention, another semiconductor device having assist features is provided. The semiconductor device comprises a substrate having at least an active region and a peripheral region defined thereon, one or more first active circuit features formed in the active region, a plurality of first assist features positioned in the peripheral region, and a plurality of second assist features electrically connecting the first assist features to one of the adjacent first active circuit features, respectively.

According to the claimed invention, a method for manufacturing a semiconductor device having assist features is further provided. The method comprises steps of providing a substrate having a conductive layer and a photoresist layer formed thereon, performing a first exposure process to form at least a first active circuit feature, a second active circuit feature, and a plurality of first assist features in the photoresist layer, performing a second exposure process and a development process to pattern the photoresist layer to remove a portion of the first assist features, and performing an etching process to etch the conductive layer through the photoresist layer to transfer the first active circuit feature, the second active circuit feature, and the first assist features to the conductive layer.

According to the claimed invention, another method for manufacturing a semiconductor device having assist features is further provided. The method comprises steps of providing a substrate having a conductive layer and a photoresist layer formed thereon, performing a first lithography process to pattern the photoresist layer to form at least a first active circuit feature, a second active circuit feature, and a plurality of first assist features, performing a first etching process to etch the conductive layer through the photoresist layer to transfer the first active circuit feature, the second active circuit feature, and the first assist features to the conductive layer, performing a second lithography process to remove a portion of the first assist features, and performing a second etching process to etch the conductive layer through the photoresist layer to remove a portion of the conductive layer corresponding to the first assist features.

According to the semiconductor device having assist features provided by the present invention, the assist features are positioned in the peripheral regions, and can also be positioned in the active region without affecting formation and performance of the active circuit, for improving uniformity of iso/dense regions. Furthermore, because the assist features provided by the present invention are made electrically connected to the active circuits, the assist features further are able to serve as redundant circuits for repairing or replacing defective circuits.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-6 are schematic drawings illustrating a first preferred embodiment of the method for manufacturing a semiconductor having assist features.

FIGS. 7-8 are schematic drawings illustrating a second preferred embodiment of the method for manufacturing a semiconductor having assist features.

FIGS. 9-11 are schematic drawings illustrating a third preferred embodiment of the method for manufacturing a semiconductor having assist features.

### DETAILED DESCRIPTION

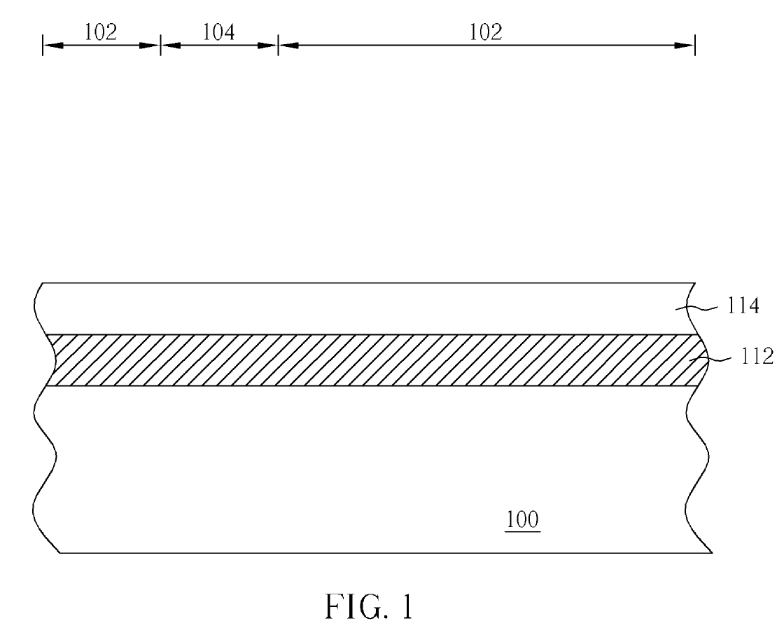

Please refer to FIGS. 1-6, which are schematic drawings illustrating a first preferred embodiment of the method for manufacturing a semiconductor having assist feature provided by the present invention. As shown in FIG. 1, a substrate 100 having an active region 102 and a peripheral region 104 defined thereon is provided. The substrate 100 comprises a conductive layer 112, such as a polysilicon layer, and a photoresist layer 114 formed thereon. Additionally, layers such as a hard mask (not shown) or a capping layer (not shown) can be formed between the photoresist layer 114 and the conductive layer 112.

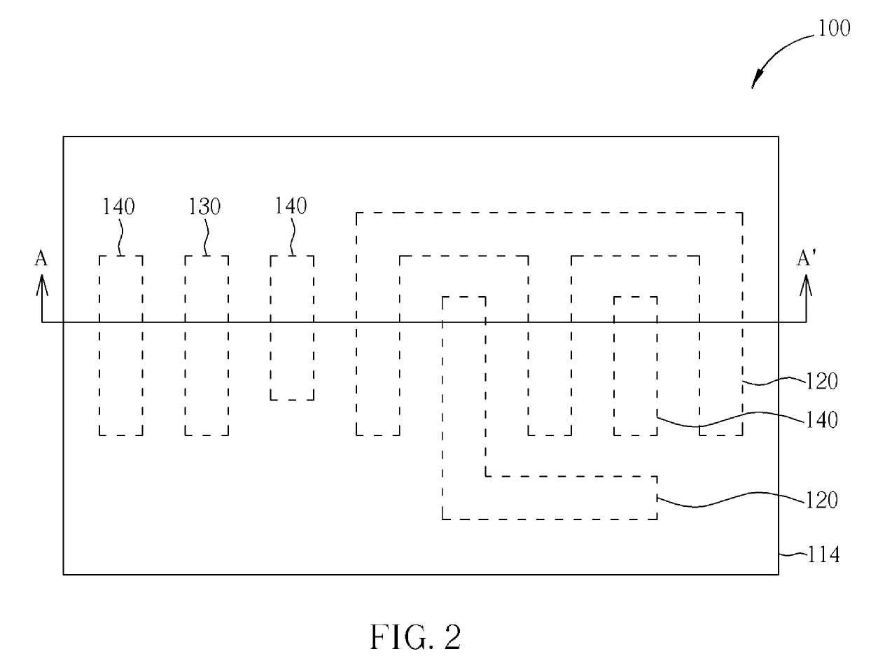

Please refer to FIG. 2. Next, a first exposure process is performed with a photomask (not shown) satisfied with optical proximity correction (OPC) to form at least a first active circuit feature 120, at least a second active circuit feature 130, and a plurality of first assist features 140 in the photoresist layer 114. It is noteworthy that there is a feature density variation between the first active circuit feature 120 and the second active circuit feature 130. As shown in FIG. 2, the first active circuit feature 120 is a dense feature while the second active circuit feature 130 is an iso feature, therefore the first assist features 140 positioned in between the first active circuit feature 120 and the second active circuit feature 130 are used to improve the feature density variation and uniformity of the wafer surface. Since the first assist features 140 are used to improve feature density variation, the first assist features 140 are defined if no device feature is defined on the photomask after shifting a pitch, but the invention is not limited to this. Consequently, the first assist features 140 are positioned between the first active circuit features 120 and the second active circuit feature 130. Furthermore, the first assist features 140 can be positioned both in the active region 102 and the peripheral region 104.

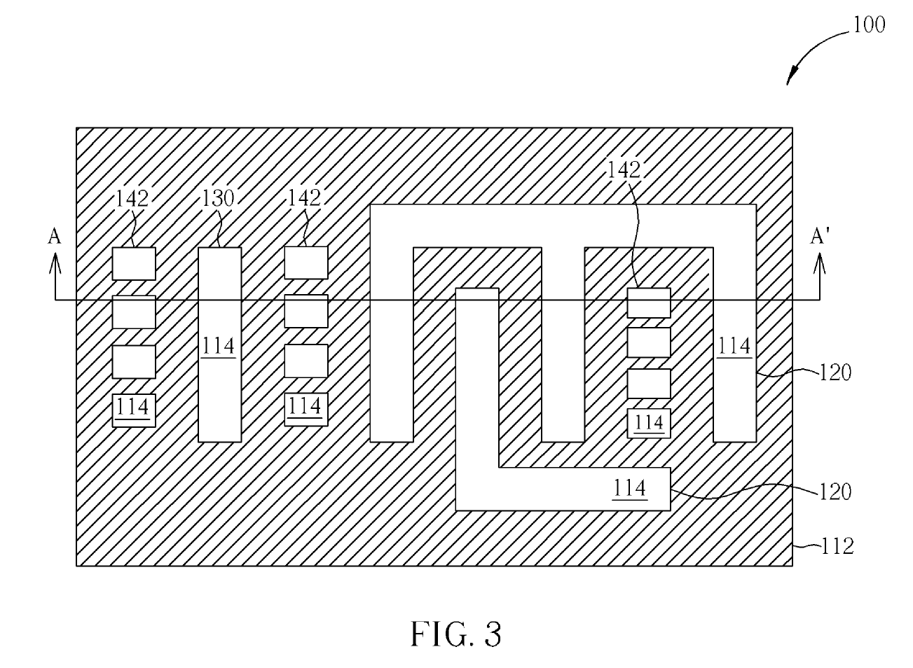

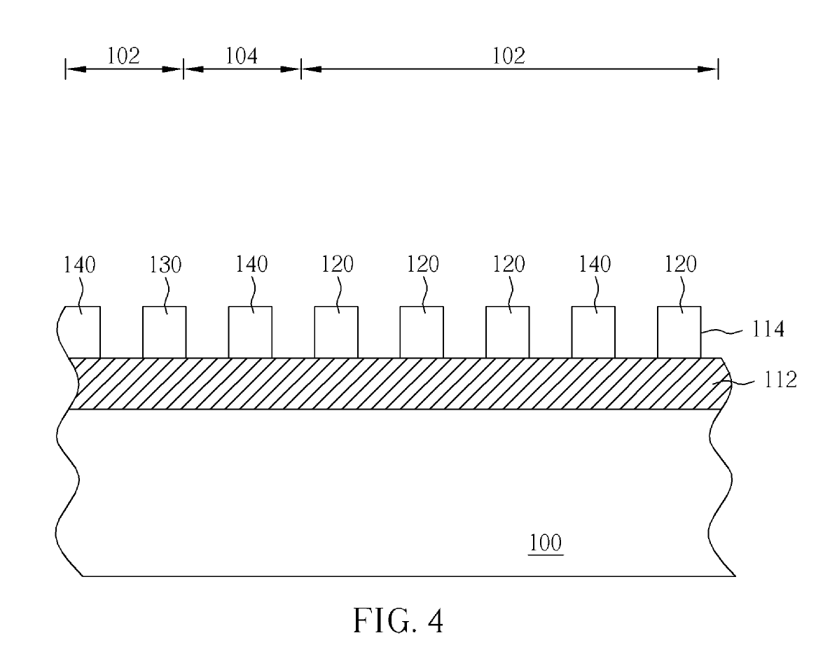

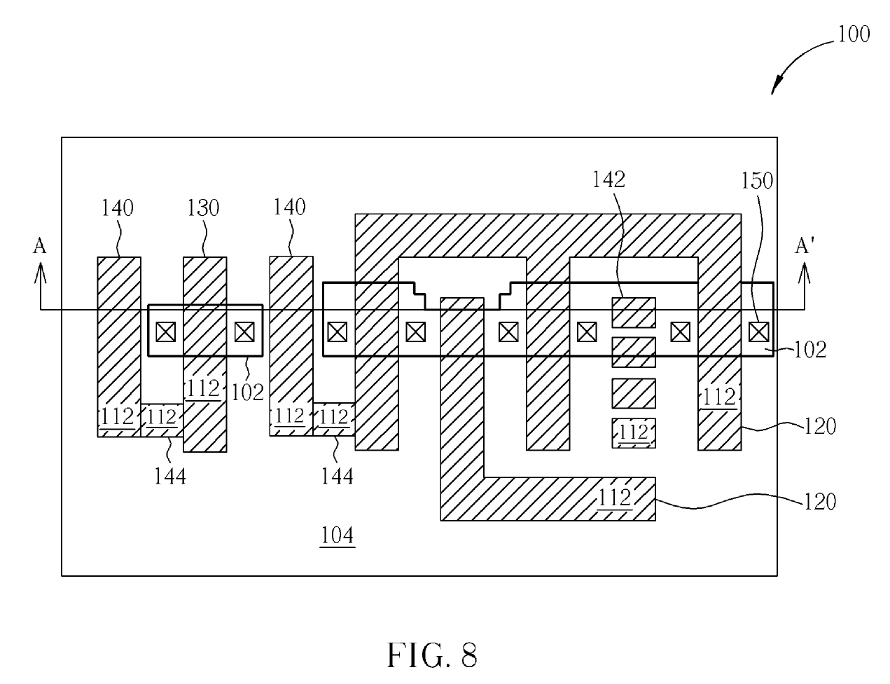

Please refer to FIG. 3-4, FIG. 4 is a cross-sectional view taken along line A-A′ of FIG. 3. Then, a second exposure process is performed with a second photomask (not shown) and followed by a development process to pattern the photoresist layer 114 and to selectively remove a portion of the first assist features 140. Therefore dotted first assist features 142 that are arranged in a dotted line pattern are obtained. Please note that though the dotted first assist features 142 are formed both in active region 102 and the peripheral region 104 as shown in FIG. 3, it is not limited that the dotted first assist features 142 are positioned only in the active region 102, as shown in FIG. 8. As CD keeps shrinking, it is getting difficult to completely form the dotted first assist features 142 by one exposure and development process, therefore two exposure processes and one development process are rendered to form the dotted first assist features 142 in the first preferred embodiment.

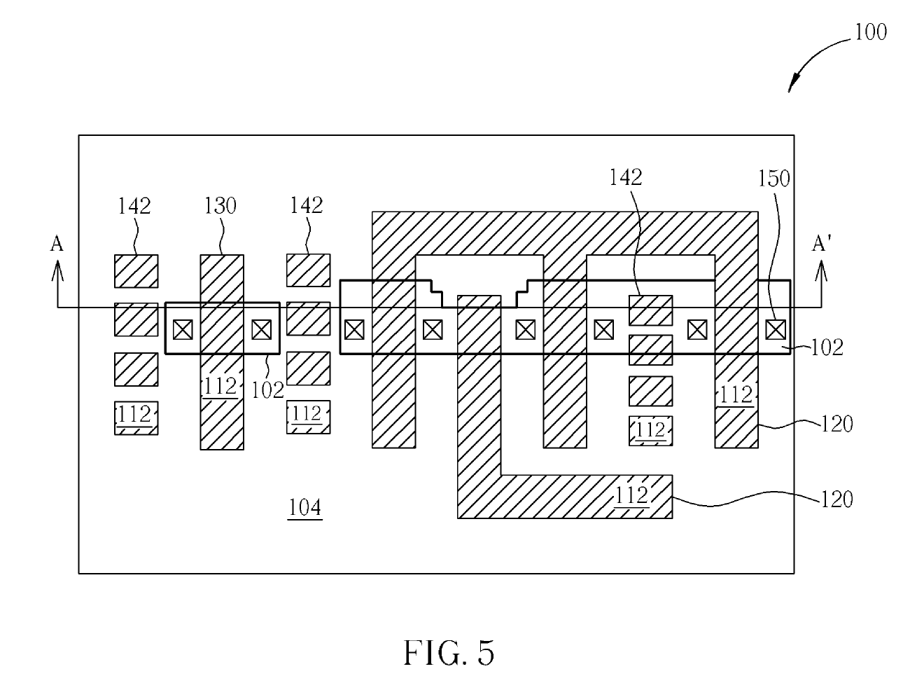

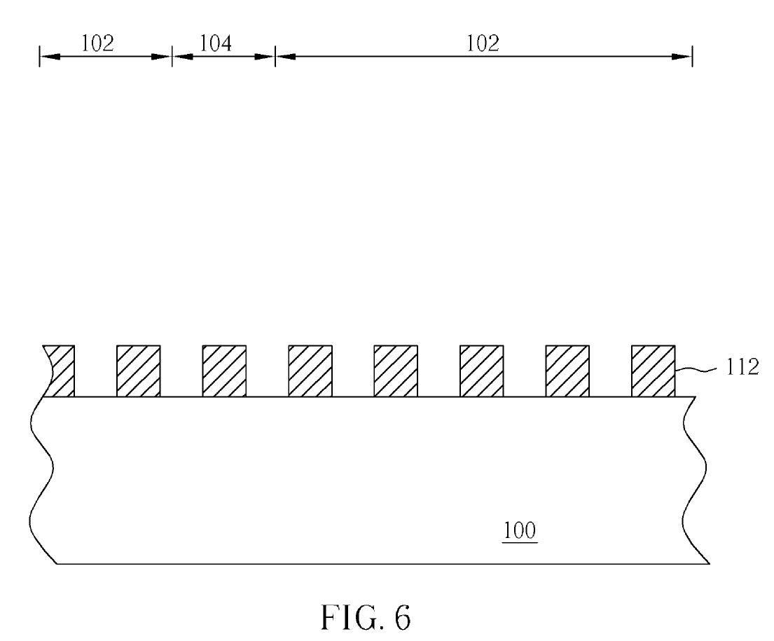

Please refer to FIGS. 5 and 6. FIG. 6 is a cross-sectional view taken along line A-A′ of FIG. 5. Next, an etching process is performed to etch the conductive layer 112 through the patterned photoresist layer 114 to transfer the first active circuit feature 120, the second active circuit feature 130, and the dotted first assist features 142 to the conductive layer 112, and followed by removing the photoresist layer 114.

Please still refer to FIG. 5. In the first preferred embodiment, the conductive layer 112 is a polysilicon layer, therefore portions of the first active circuit feature 120 serve as a gate feature. Thus procedures for fabricating transistor are performed after the first active circuit feature 120 is transferred to the conductive layer 112 by the etching process. For instance, ion implantations of different conductive types are performed to form doped regions 150, such as light doped drain (LDD) or source/drain, in the substrate 100. It is noteworthy that the doped ions are allowed to enter the substrate 100 at intervals of the dotted first assist features 142 in the active region 102. It is observed that the dotted first assist feature 142, which is positioned in the active region 102, does not affect formation of the LDD or source/drain. Accordingly, in the first preferred embodiment, first active circuits at two sides of the dotted first assist feature 142 possess a common source/drain, and the dotted first assist feature 142 will not affect formation and performance of the common source/drain.

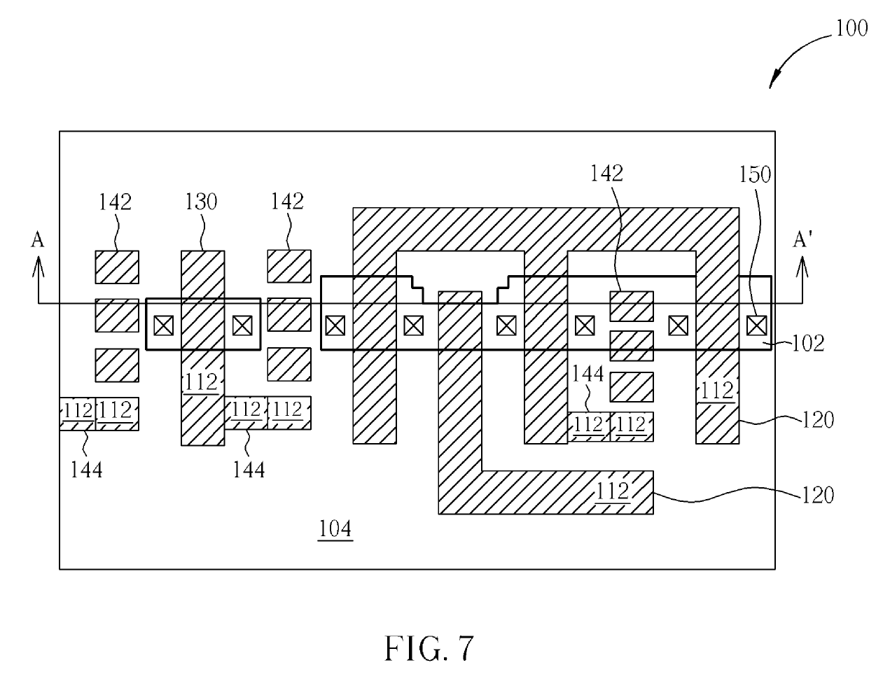

Please refer to FIGS. 7 and 8, which are drawings of a second preferred embodiment provided by the present invention. Please note that steps and drawings, which are similar with the first preferred embodiment, are omitted herein in the interest of brevity. In the second preferred embodiment, the first exposure process is performed to form not only the first active circuit feature 120, the second active circuit feature 130, and the first assist features 140 in the photoresist layer 114, but also a plurality of second assist features 144 in the photoresist layer 114. And the second assist features 144 are transferred to the conductive layer by the etching process as shown in FIG. 7. The second assist features 144 are used to connect the dotted first assist feature 142 to one of the adjacent first active circuit feature 120, or to one of the adjacent second active circuit feature 130, respectively. The second assist features 144 are rendered to enable the dotted first assist features 142 to be redundant circuits for repairing or replacing defective circuits. As mentioned above, since there is a feature density variation between the second active circuit feature 130 and the first active circuit feature 120, the dotted first assist features 142 are positioned in between the second active circuit features 130, or in between the first active circuit features 120 and the second active circuit features 130 for improving the feature density variation and uniformity.

Please further refer to FIG. 8, which illustrates that the dotted first assist feature 142 is positioned only in the active region 102 as a modification of the second preferred embodiment. Additionally, the first assist features 140 are positioned in the peripheral region 104. In other words, the first assist features 140 are positioned in between the second active circuit features 130, or in between the first active circuit feature 120 and the second active circuit feature 130 for improving the feature density variation and uniformity. As mentioned above, the first assist features 140 are electrically connected to one of the adjacent first active circuit feature 120 or one of the adjacent second active circuit feature 130 by the second assist feature 144, respectively. Thus, the first assist features 140 are enabled to be the redundant circuits.

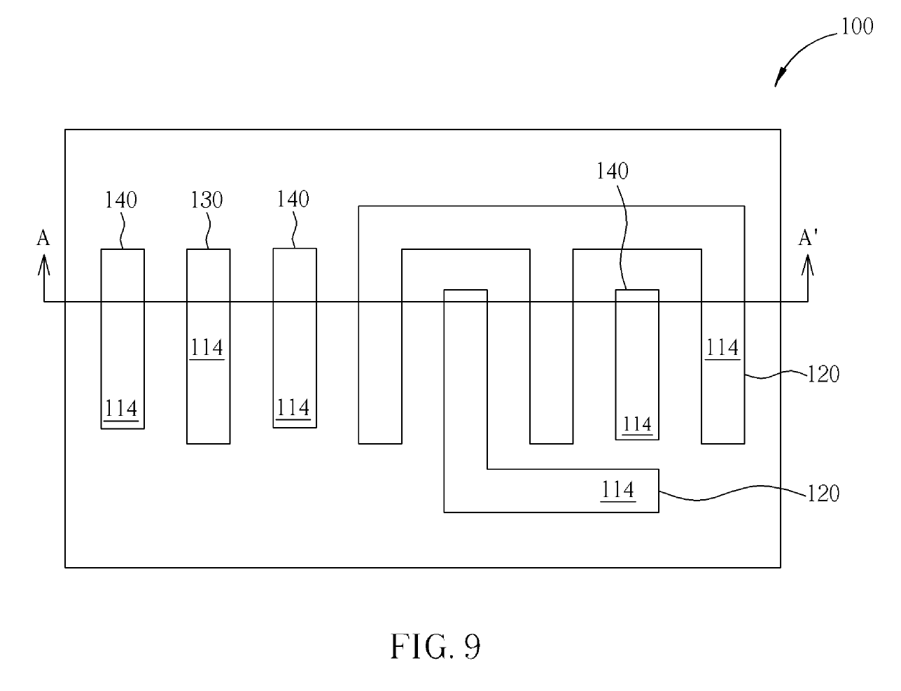

Please refer to FIGS. 9-11, which are schematic drawings illustrating a third preferred embodiment of the method for manufacturing a semiconductor having assist features provided by the present invention. Since some steps of the third preferred embodiment are similar with the first preferred embodiment, FIGS. 1 and 4 of the first preferred embodiment can be referred as the corresponding drawing. As shown in FIG. 1, a substrate 100 having a conductive layer 112, such as a polysilicon layer, and a photoresist layer 114 formed thereon is provided. As shown in FIG. 4, a first lithography process is performed to pattern the photoresist layer 114 to form at least a first active circuit feature 120, at least a second active circuit feature 130, and a plurality of first assist features 140.

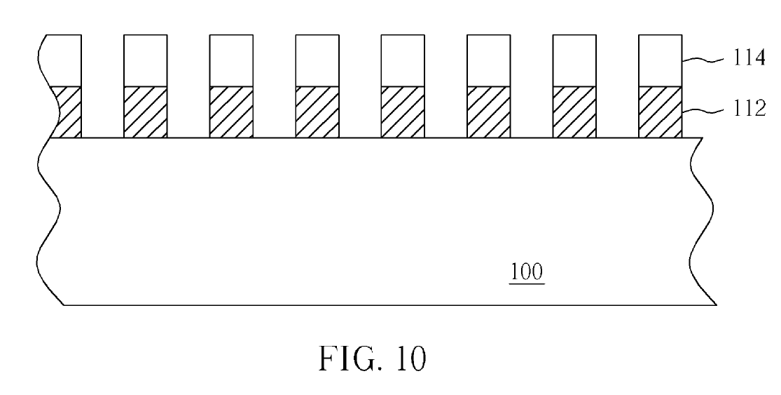

Please refer to FIGS. 9-10. FIG. 10 is a cross-sectional view taken along line A-‘A’ of FIG. 9. Next, a first etching process is performed to etch the conductive layer 112 through the patterned photoresist layer 114. Thus the first active circuit feature 120, the second active circuit feature 130, and the first assist features 140 are transferred to the conductive layer 112.

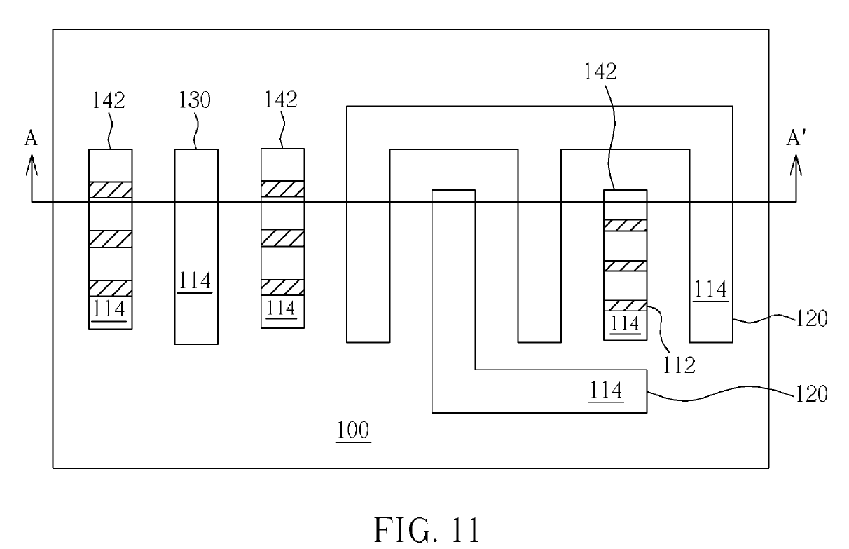

Please refer to FIG. 11. Then, a second lithography process is performed with another photoresist layer (not shown) to remove a portion of the photoresist layer 114. In other words, the second lithography process is performed to remove a portion of the first assist features 104 to form dotted first assist features 142. Then, a second etching process is performed to etch the conductive layer 112 through the photoresist layer 114 to remove a portion of the conductive layer 112, and followed by removing the photoresist layer 114. Thus the dotted first assist features 142 are obtained as shown in FIG. 5. As mentioned above, though the dotted first assist features 142 are positioned both in the active region 102 and the peripheral region 104, the present invention is not limited as described in the third preferred embodiment. The dotted first assist features 142 can be formed only in the active region 102. As mentioned above, because CD keeps shrinking, it is getting difficult to form the dotted first assist feature 142 completely by one lithography process and one etching process. Thus the second lithography process and the second etching process are rendered to form the dotted first assist features 142 in the third preferred embodiment. As mentioned above, the dotted first assist features 142 allow the doped ions to enter the substrate 100 at intervals of the dotted first assist features 142. Therefore formation of the doped region and performance of the active circuit will not be affected.

Additionally, a plurality of second assist features 144 are formed in the photoresist layer 114 simultaneously with forming the first assist features 140 in the first lithography process and followed by being transferred to the conductive layer 112 by the first etching process. The second assist feature 144 respectively connects the first assist feature 104 or the dotted first assist feature 142 to one of the adjacent first active circuit feature 120, or to one of the adjacent second active circuit feature 130. Therefore the first assist features 140/dotted first assist features 142 are enabled to be redundant circuits for repairing or replacing defective circuits. Since such steps and modification have been shown in FIGS. 7-8, further details are omitted for brevity.

According to the semiconductor device having assist features provided by the present invention, the assist features are positioned in the peripheral regions, and can also be positioned in the active region without affecting formation and performance of the active circuit, while the assist features are used to improve uniformity of iso/dense regions. Since the uniformity is improved by the application of the assist features, conventional methods for avoiding loading effect in planarization process such as intentionally forming a thicker dielectric layer can be omitted. Accordingly, process time and cost are both economized. Furthermore, because the assist features provided by the present invention are made electrically connected to the active circuits, the assist features further are able to serve as redundant circuits for repairing or replacing defective circuits.

Those skilled in the art will readily observe that numerous modifications and alterations of the device and method may be made while retaining the teachings of the invention.

What is claimed is:

1. A semiconductor device having assist features comprising:
a substrate having an active region defined thereon;
one or more first active circuit features formed in the active region; and
a plurality of dotted first assist features positioned between portions of the first active circuit feature in the active region.

2. The semiconductor device of claim 1, wherein the first active circuit feature comprises a polysilicon gate pattern.

3. The semiconductor device of claim 2 further comprising at least a source/drain positioned under the dotted first assist feature.

4. The semiconductor device of claim 1 further comprising a plurality of second assist features electrically connecting the dotted first assist features to one of the adjacent first active circuit features, respectively.

5. The semiconductor device of claim 1 further comprising at least a second active circuit feature, and the second active circuit feature comprises a feature density variation from the first active circuit feature.

6. The semiconductor device of claim 5, wherein the dotted first assist features are positioned in between portions of the second active circuit feature.

7. The semiconductor device of claim 5, wherein the dotted first assist features are positioned in between the first active circuit feature and the second active circuit feature.

8. A semiconductor device having assist features comprising:
a substrate having at least an active region and a peripheral region defined thereon;
one or more first active circuit features formed in the active region;
a plurality of first assist features positioned in the peripheral region; and
a plurality of second assist features electrically connecting the first assist features to one of the adjacent first active circuit features, respectively.

9. The semiconductor device of claim 8, wherein the first assist features comprise dotted line patterns.

10. The semiconductor device of claim 9 further comprising at least a second active circuit feature, and a feature density variation between the second active circuit feature and the first active circuit feature.

11. The semiconductor device of claim 10, wherein the first assist features are positioned in between portions of the second active circuit feature.

12. The semiconductor device of claim 10, wherein the first assist features are positioned in between the first active circuit feature and the second active circuit feature.

13. The semiconductor device of claim 10, wherein the second assist features electrically connect the first assist features to one of the adjacent second active circuit features, respectively.

14. A method for manufacturing a semiconductor device having assist features comprising steps of:
providing a substrate having a conductive layer and a photoresist layer formed thereon;
performing a first exposure process to form one or more first active circuit features, one or more second active circuit features, and a plurality of first assist features in the photoresist layer;
performing a second exposure process and a development process to pattern the photoresist layer to remove a portion of the first assist features; and
performing an etching process to etch the conductive layer through the photoresist layer to transfer the first active circuit feature, the second active circuit feature, and the first assist features to the conductive layer.

15. The method of claim 14, wherein the first exposure process is performed to further form a plurality of second assist features connecting the first assist features to one of the adjacent first active circuit features or to one of the adjacent second active circuit features, respectively.

16. The method of claim 15, wherein the etching process is performed to transfer the second assist features to the conductive layer.

17. The method of claim 14, wherein the conductive layer comprises a polysilicon layer.

18. The method of claim 17, wherein the second exposure process is performed to remove a portion of the first assist feature to form a dotted line pattern.

19. The method of claim 18 further comprising a step of performing an ion implantation to form at least a source/drain in the substrate after the etching process.

20. A method for manufacturing a semiconductor device having assist features comprising steps of:
providing a substrate having a conductive layer and a photoresist layer formed thereon;
performing a first lithography process to pattern the photoresist layer to form one or more first active circuit features, one or more second active circuit features, and a plurality of first assist features;
performing a first etching process to etch the conductive layer through the photoresist layer to transfer the first active circuit feature, the second active circuit feature, and the first assist features to the conductive layer;
performing a second lithography process to remove a portion of the first assist features; and
performing a second etching process to etch the conductive layer through the photoresist layer to remove a portion of the conductive layer.

21. The method of claim 20, wherein the first lithography process is performed to pattern the photoresist layer to form a plurality of second assist features respectively connecting the first assist features to one of the adjacent first active circuit features or to one of the adjacent second active circuit features.

22. The method of claim 21, wherein the first etching process is performed to transfer the second assist features to the conductive layer.

23. The method of claim 20, wherein the conductive layer comprises a polysilicon layer.

24. The method of claim 20, wherein the second lithography process is performed to remove a portion of the first assist feature to form a dotted line pattern.

25. The method of claim 24 further comprising a step of performing an ion implantation to form at least a source/drain in the substrate after the etching process.
